(19) United States
(12) Patent Application Publication
(10) Pub. No.: US 2024/0145254 A1
(43) Pub. Date: May 2, 2024

(54) CHEMICAL MECHANICAL POLISHING APPARATUS AND METHOD OF FABRICATING SEMICONDUCTOR DEVICE USING THE SAME

(71) Applicant: SAMSUNG ELECTRONICS CO., LTD., Suwon-si (KR)

(72) Inventors: Hyo-Jung KIM, Suwon-si (KR); Dong Hoon KWON, Suwon-si (KR)

(21) Appl. No.: 18/328,298

(22) Filed: Jun. 2, 2023

(30) Foreign Application Priority Data
Oct. 26, 2022 (KR) 10-2022-0138923

(51) Int. Cl. H01L 21/321; H01L 21/02; H01L 21/304; H01L 21/67

(52) U.S. Cl. CPC H01L 21/3212; H01L 21/02024; H01L 21/3043; H01L 21/67219

(57) ABSTRACT

A chemical mechanical polishing apparatus capable of controlling polishing temperature, and a method of fabricating a semiconductor device using the same are provided. The chemical mechanical polishing apparatus includes a platen, a polishing pad on the platen, the polishing pad including a plurality of grooves, and a light irradiator in the platen, the light irradiator configured to irradiate light toward the polishing pad, wherein the polishing pad includes a light transmission pattern interposed between at least some of the plurality of grooves and the light irradiator and through which the light is transmitted.

### CROSS-REFERENCE TO RELATED APPLICATION

This application claims priority to Korean Patent Application No. 10-2022-0138923 filed on Oct. 26, 2022 in the Korean Intellectual Property Office, the disclosure of which is incorporated herein by reference in its entirety.

### BACKGROUND

### 1. Technical Field

The present disclosure relates to a chemical mechanical polishing apparatus and a method of fabricating semiconductor devices using the same, and more particularly, to a chemical mechanical polishing apparatus capable of controlling polishing temperature and a method of fabricating semiconductor devices using the same.

### 2. Description of the Related Art

In a process of fabricating a semiconductor device, a chemical mechanical polishing (CMP) process may be used as a planarization technique for removing steps between layers formed on a substrate. In the chemical mechanical polishing process, the layers formed on the substrate may be efficiently planarized by injecting a polishing slurry containing abrasive particles between the substrate and a polishing pad and rubbing the substrate and the polishing pad.

In order to improve the polishing efficiency, it may be advantageous to control a temperature of the chemical mechanical polishing process.

### SUMMARY

Aspects of the present disclosure provide semiconductor devices with improved productivity and quality.

Aspects of the present disclosure also provide a chemical mechanical polishing apparatus capable of fabricating semiconductor devices with improved productivity and quality.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present inventive concept, there is provided a method of fabricating a semiconductor device, the method comprising providing a target layer on a semiconductor substrate, and performing a polishing process on the target layer using a chemical mechanical polishing apparatus, wherein the chemical mechanical polishing apparatus includes a platen, a polishing pad on the platen, the polishing pad including a plurality of grooves, and a light irradiator in the platen, the light irradiator configured to irradiate light toward the polishing pad, and wherein the polishing pad includes a light transmission pattern within at least some of the plurality of grooves and through which the light is transmitted from the light irradiator.

According to aspects of the present inventive concept, there is provided a chemical mechanical polishing apparatus comprising a platen, a polishing pad on the platen, the polishing pad including a plurality of grooves, and a light irradiator in the platen, the light irradiator configured to irradiate light toward the polishing pad, wherein the polishing pad includes a light transmission pattern within at least some of the plurality of grooves and through which the light is transmitted from the light irradiator.

According to aspects of the present inventive concept, there is provided a chemical mechanical polishing apparatus comprising a rotatable platen, a polishing pad on the platen, the polishing pad including a polishing surface, a plurality of grooves formed in the polishing surface, and a light transmission pattern within at least some of the plurality of grooves, a carrier head assembly above the polishing pad and configured to support a wafer facing the polishing surface, a slurry supplier configured to supply a polishing slurry between the wafer and the polishing pad, and a light irradiator in the platen, the light irradiator configured to irradiate light toward the light transmission pattern.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic plan view illustrating a polishing facility including a chemical mechanical polishing apparatus according to some exemplary embodiments.

FIG. 2 is a schematic perspective view illustrating the chemical mechanical polishing apparatus according to some exemplary embodiments.

FIG. 3 is a schematic perspective view illustrating a polishing pad, a platen, and a light irradiator of FIG. 2.

FIG. 4 is a schematic cross-sectional view illustrating the polishing pad, the platen, and the light irradiator of FIG. 2.

FIG. 5A is an enlarged view illustrating an R region of FIG. 4.

FIGS. 5B to 5F are other various enlarged views illustrating the R region of FIG. 4.

FIG. 6 is a schematic perspective view illustrating the polishing pad, the platen, and the light irradiator of the chemical mechanical polishing apparatus according to some exemplary embodiments.

FIG. 7 is a schematic cross-sectional view illustrating the polishing pad, the platen, and the light irradiator of FIG. 6.

FIG. 8 is a schematic perspective view illustrating the polishing pad, the platen, and the light irradiator of the chemical mechanical polishing apparatus according to some exemplary embodiments.

FIGS. 9 and 10 are various schematic cross-sectional views illustrating the polishing pad, the platen, and the light irradiator of the chemical mechanical polishing apparatus according to some exemplary embodiments.

FIG. 11 is a schematic perspective view illustrating the chemical mechanical polishing apparatus according to some exemplary embodiments.

FIG. 12 is an exemplary flowchart illustrating a method of fabricating a semiconductor device according to some exemplary embodiments.

FIGS. 13 to 16 are intermediate step drawings illustrating the method of fabricating the semiconductor device according to some exemplary embodiments.

### DETAILED DESCRIPTION OF THE EMBODIMENTS

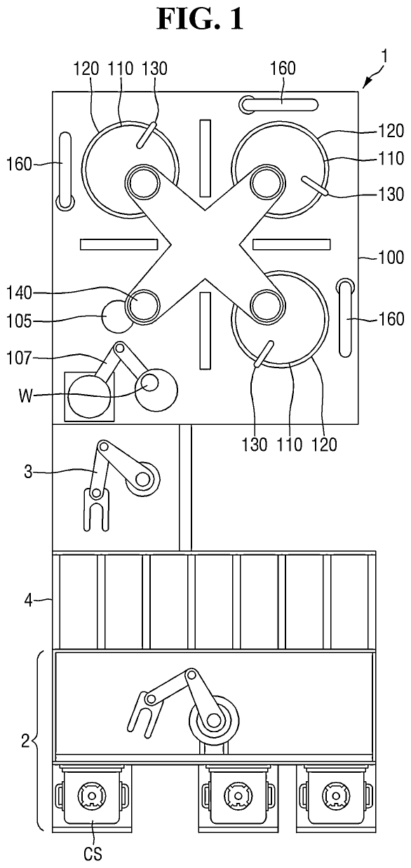

Hereinafter, a chemical mechanical polishing apparatus according to exemplary embodiments will be described with reference to FIGS. 1 to 11. However, the following exemplary embodiments are merely illustrative, and the present disclosure is not limited to the exemplary embodiments.

FIG. 1 is a schematic plan view illustrating a polishing facility including a chemical mechanical polishing apparatus according to some exemplary embodiments.

Referring to FIG. 1, a polishing facility according to some exemplary embodiments includes a chemical mechanical polishing apparatus 1, an index portion 2, a transfer robot 3, and a cleaning apparatus 4.

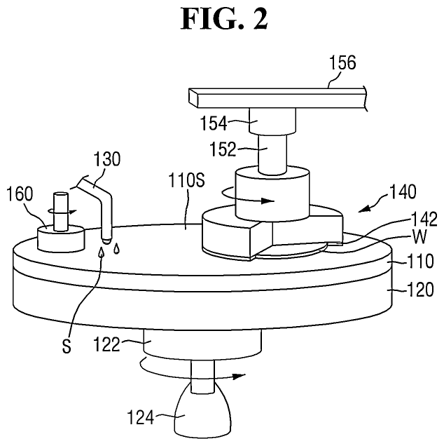

The chemical mechanical polishing apparatus 1 may perform a polishing process on the wafer W. In some exemplary embodiments, the chemical mechanical polishing apparatus 1 may include a polishing pad 110, a platen 120, a slurry supplier 130, a carrier head assembly 140, and a pad conditioner 160 disposed on a lower base 100. The chemical mechanical polishing apparatus 1 will be described later in more detail with reference to FIGS. 2 to 11.

The index portion 2 may provide a space in which a cassette CS in which the wafers W are stored is placed. The index portion 2 may take out the wafer W from the cassette CS and transfer the wafer W to the transfer robot 3, or may carry the wafer W on which the polishing process is completed into the cassette CS.

The transfer robot 3 may be provided between the chemical mechanical polishing apparatus 1 and the index portion 2. The transfer robot 3 may transfer the wafer W between the chemical mechanical polishing apparatus 1 and the index portion 2. For example, a load cup 105 adjacent to the transfer robot 3 may be disposed in the chemical mechanical polishing apparatus 1. The load cup 105 may provide a space for the wafer W to temporarily stand by. In addition, an exchanger 107 may be provided between the transfer robot 3 and the load cup 105. The exchanger 107 may transfer the wafer W transferred from the index portion 2 by the transfer robot 3 to the load cup 105 or transfer the wafer W disposed on the load cup 105 to the transfer robot 3.

The cleaning apparatus 4 may be provided between the index portion 2 and the transfer robot 3. The wafer W polished in the chemical mechanical polishing apparatus 1 may be disposed on the load cup 105. The wafer W disposed on the load cup 105 may be transferred to the cleaning apparatus 4 by the transfer robot 3 disposed adjacent to the load cup 105. The cleaning apparatus 4 may clean contaminants remaining on the polished wafer W. The cleaned wafer W may be returned to the index portion 2 and stored in the cassette CS. Accordingly, the polishing process of the wafer W may be completed.

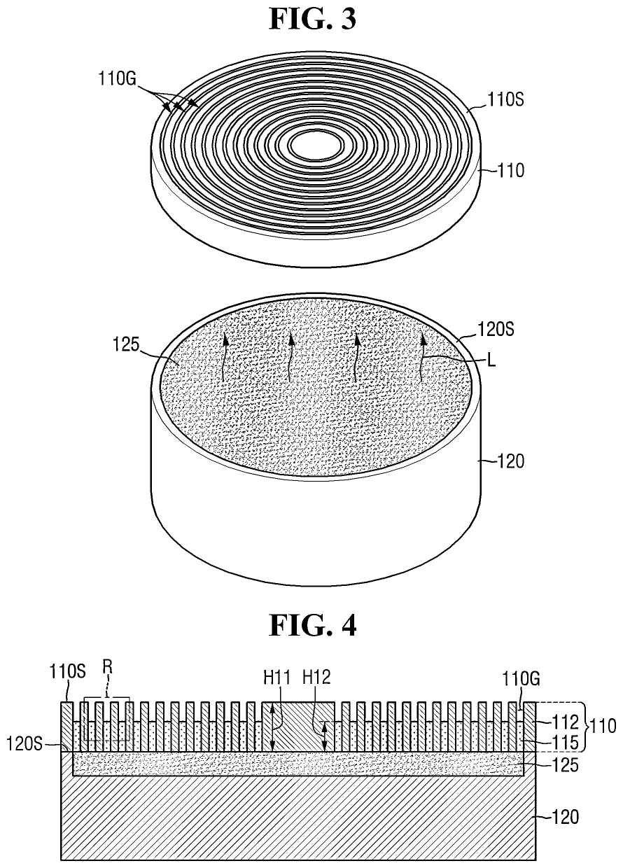

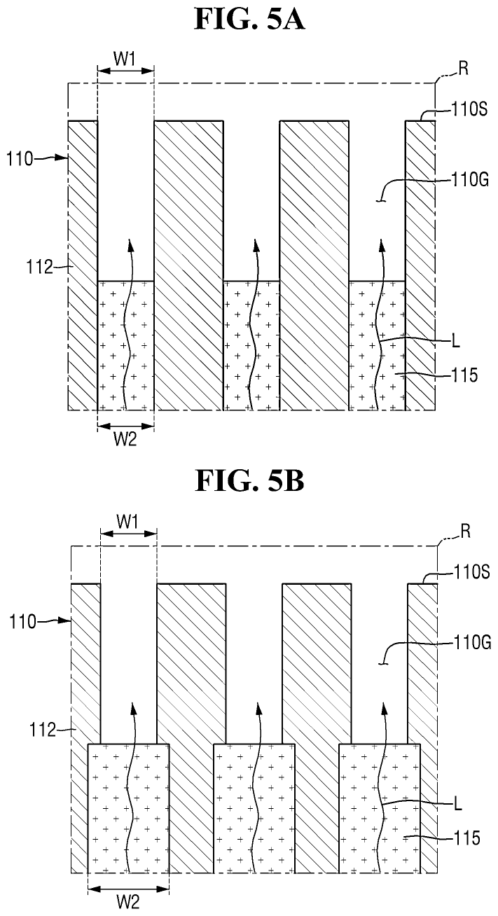

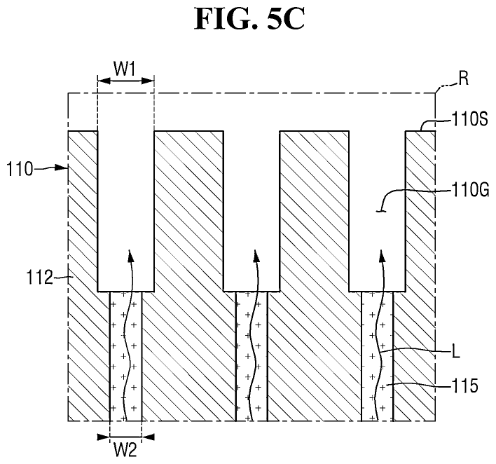

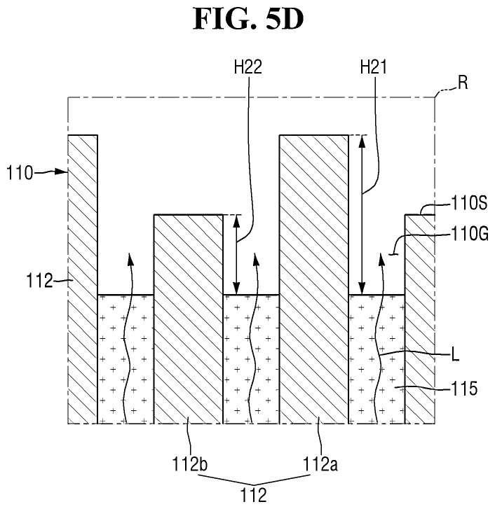

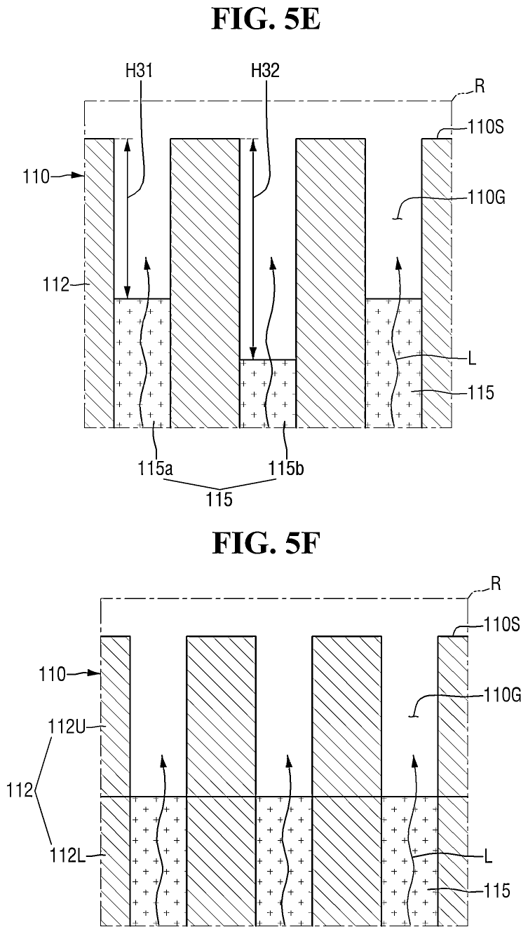

FIG. 2 is a schematic perspective view illustrating the chemical mechanical polishing apparatus according to some exemplary embodiments. FIG. 3 is a schematic perspective view illustrating a polishing pad, a platen, and a light irradiator of FIG. 2. FIG. 4 is a schematic cross-sectional view illustrating the polishing pad, the platen, and the light irradiator of FIG. 2. FIG. 5A is an enlarged view illustrating an R region of FIG. 4.

Referring to FIGS. 2 to 5A, the chemical mechanical polishing apparatus according to some exemplary embodiments includes a polishing pad 110, a platen 120, a light irradiator 125, a slurry supplier 130, a carrier head assembly 140, and a pad conditioner 160.

The polishing pad 110 may be disposed on the platen 120. The polishing pad 110 may be provided in the form of a plate having a certain thickness, for example, in the form of a circular plate, but is not limited thereto. The polishing pad 110 may include a polishing surface 110S facing the wafer W. The polishing surface 110S may have a predetermined roughness. While the polishing process is being performed, the polishing surface 110S may be in contact with the wafer W to polish the wafer W.

The polishing pad 110 may include a plurality of grooves 110G. The grooves 110G may be formed in the polishing surface 110S of the polishing pad 110. For example, each of the grooves 110G may be drawn in from the polishing surface 110S. That is, a lower surface of each of the grooves 110G may be recessed from the polishing surface 110S. A depth at which the grooves 110G are formed may be, for example, about 0.5 mm to about 1.5 mm, but is not limited thereto. While the polishing process is being performed, the grooves 110G are provided as passages for a polishing slurry S to facilitate a flow of the polishing slurry S.

Although it is illustrated in FIG. 3 that the grooves 110G are only formed in a concentric circle shape in plan view, but this is only an example, and the shape in which the grooves 110G are formed may also be variously modified. As another example, the grooves 110G may be formed in a spiral shape. As still another example, at least some of the grooves 110G may extend from a center of the polishing surface 110S to an edge of the polishing surface 110S.

The platen 120 may support the polishing pad 110. For example, the polishing pad 110 may be disposed on an upper surface 120S of the platen 120. In addition, the platen 120 may be rotatable. The rotatable platen 120 may rotate the polishing pad 110 disposed on the platen 120. For example, a first driving shaft 122 connected to a lower portion of the platen 120 may be rotated by receiving rotational power from a first motor 124. The platen 120 may rotate the polishing pad 110 around a rotational axis perpendicular to the upper surface of the platen 120.

The light irradiator 125 may be disposed within the platen 120. The light irradiator 125 may irradiate light L toward the polishing pad 110 disposed on the platen 120. For example, the light irradiator 125 may be exposed through the upper surface 120S of the platen 120 on which the polishing pad 110 is disposed. In other words, the upper surface 120S is configured such that the light irradiator 125 is exposed in at least one or more portions thereof (i.e., the upper surface has one or more openings through which light can pass.) In FIG. 4, there is a single large opening that exposes the light irradiator 125. The light irradiator 125 may be, for example, a light source such as a lamp or a laser, but is not limited thereto.

The slurry supplier 130 may be disposed adjacent to the polishing pad 110. While the polishing process is being performed, the slurry supplier 130 may supply the polishing slurry S onto the polishing surface 110S of the polishing pad 110. The polishing slurry S may be smoothly supplied between the wafer W and the polishing pad 110 through the grooves 110G formed in the polishing surface 110S.

In some exemplary embodiments, the polishing slurry S may include a plurality of abrasive particles. For example, the polishing slurry S may include a reactive agent and/or a chemical reaction catalyst in which the abrasive particles are dispersed. The abrasive particles may function as an abrasive. The abrasive particles may include, for example, metal oxide, metal oxide coated with organic or inorganic materials, or metal oxide in a colloidal state. For example, the abrasive particles may include at least one of silica, alumina, ceria, titania, zirconia, magnesia, germania, mangania, and a combination thereof, but are not limited thereto.

The carrier head assembly 140 may be disposed adjacent to the polishing pad 110. The carrier head assembly 140 may provide the wafer W on the polishing surface 110S of the polishing pad 110. For example, the carrier head assembly 140 may operate to hold the wafer W against the polishing pad 110.

In some exemplary embodiments, the carrier head assembly 140 may independently control polishing parameters (e.g., pressure, etc.) related to each of the wafers W. For example, the carrier head assembly 140 may include a retaining ring 142 for retaining the wafer W below a flexible membrane. The carrier head assembly 140 may include a plurality of independently controllable pressurizable chambers defined by the flexible membrane. The pressurizable chambers may apply independently controllable pressure to relevant areas on the flexible membrane or to relevant areas on the wafer W.

The carrier head assembly 140 may be rotatable. The rotatable carrier head assembly 140 may rotate the wafer W fixed to the carrier head assembly 140. For example, a second driving shaft 152 connected to an upper portion of the carrier head assembly 140 may be rotated by receiving rotational power from a second motor 154.

The carrier head assembly 140 may be supported by a support structure 156. The support structure 156 may be, for example, a carousel or a track, but is not limited thereto. In some exemplary embodiments, the carrier head assembly 140 may laterally translate across the upper surface of the polishing pad 110. For example, the carrier head assembly 140 may vibrate on a slider of the support structure 156 or by rotational vibration of the support structure 156 itself.

Although it is illustrated in FIG. 2 that only one carrier head assembly 140 is provided on the polishing pad 110, this is only an example. As another example, in order to efficiently use a surface area of the polishing pad 110, a plurality of carrier head assemblies 140 may also be provided on the polishing pad 110. In addition, although it is illustrated in FIG. 2 that a rotational direction of the platen 120 and a rotational direction of the carrier head assembly 140 are the same, this is only an example and the platen 120 and the carrier head assembly 140 may rotate in different rotation directions.

The pad conditioner 160 may be disposed adjacent to the polishing pad 110. The pad conditioner 160 may perform a conditioning process on the polishing surface 110S of the polishing pad 110. Through this, the pad conditioner 160 may stably maintain the polishing surface 110S of the polishing pad 110 so that the wafer W is effectively polished during the polishing process. For example, the pad conditioner 160 may polish the polishing surface 110S damaged in the CMP process to recover and maintain the performance of the polishing surface 110S.

As illustrated in FIGS. 4 and 5A, the polishing pad 110 may include a light transmission pattern 115. For example, the polishing pad 110 may include a base pattern 112 and a light transmission pattern 115 retained within the base pattern 112. The light transmission pattern 115 may be disposed to correspond to at least some of the plurality of grooves 110G. Specifically, the light transmission pattern 115 may be disposed to overlap at least some of the plurality of grooves 110G in a direction (hereinafter, referred to as a vertical direction) intersecting the polishing surface 110S. As an example, when the grooves 110G are formed in a concentric circle shape, the light transmission pattern 115 may also be formed in a concentric circle shape. In this case, the base pattern 112 and the light transmission pattern 115 may be alternately arranged in a direction (hereinafter, referred to as a horizontal direction) parallel to the polishing surface 110S. In some exemplary embodiments, the light transmission pattern 115 may be formed to correspond to all grooves 110G of the polishing pad 110. The illustrated base pattern 112 is a material comprising a plurality of concentric ring members. The light transmission pattern 115 is a light transmissive material that is placed between adjacent ones of the concentric ring members of the base pattern 112.

The base pattern 112 may include a material having excellent strength, flexibility, and durability in order to retain the light transmission pattern 115. For example, the base pattern 112 may include a polymer such as polyurethane, polyester, polyether, felt, epoxy, polyimide, polycarbonate, polyethylene, polypropylene, latex, nitrile-butadiene rubber (NBR), isoprene rubber, and a combination thereof, but is not limited thereto.

In some exemplary embodiments, an upper surface of the light transmission pattern 115 may define lower surfaces of at least some of the plurality of grooves 110G. For example, the light transmission pattern 115 may extend from the lower surface of the polishing pad 110 to the lower surface of the groove 110G.

In some exemplary embodiments, the base pattern 112 may define side surfaces of the plurality of grooves 110G. For example, a portion of the base pattern 112 may upwardly protrude compared to the upper surface of the light transmission pattern 115. That is as illustrated in FIG. 4, based on the lower surface of the polishing pad 110, a height H11 at which the base pattern 112 is formed may be greater than a height H12 at which the light transmission pattern 115 is formed. Through this, the grooves 110G defined by the side surface of the base pattern 112 and the upper surface of the light transmission pattern 115 may be formed.

In some exemplary embodiments, a lower surface of the base pattern 112 and a lower surface of the light transmission pattern 115 may be coplanar. That is, the base pattern 112 and the light transmission pattern 115 may define the lower surface of the polishing pad 110.

The light irradiator 125 may irradiate light L toward the light transmission pattern 115. For example, the light irradiator 125 and the light transmission pattern 115 may be disposed to overlap each other in the vertical direction. The light transmission pattern 115 may be interposed between at least a portion of the groove 110G and the light irradiator 125. The light L irradiated from the light irradiator 125 may transmit through the light transmission pattern 115. For example, the light transmission pattern 115 may be formed of a material through which the light L irradiated from the light irradiator 125 may transmit. As an example, the light transmission pattern 115 may include a transparent polymer, but is not limited thereto.

The light L transmitted through the light transmission pattern 115 may be provided to the polishing slurry S supplied on the polishing pad 110 to heat the polishing slurry S. Since the light transmission pattern 115 may be formed to correspond to at least some of the grooves 110G, the light L transmitted through the light transmission pattern 115 may efficiently heat the polishing slurry S flowing through the grooves 110G.

In some exemplary embodiments, the light L irradiated from the light irradiator 125 may include infrared light. The light L including infrared light has a high transmittance compared to other rays having relatively short wavelengths such as ultraviolet, and may thus more efficiently heat the polishing slurry S. In other words, nearly all of the infrared light is capable of passing through the light transmission pattern 115 without being absorbed, as compared with other, shorter wavelengths of light.

In some exemplary embodiments, when the light L includes infrared, the light transmission pattern 115 may include a transparent polymer having a high infrared transmittance. As an example, the light transmission pattern 115 may include at least one of polyethylene and polyethylene terephthalate, but is not limited thereto.

In some exemplary embodiments, the light irradiator 125 may overlap a plurality of light transmission patterns 115. For example, as illustrated in FIGS. 3 and 4, the light irradiator 125 may be provided in a plate shape (e.g., a circular plate shape). The light irradiator 125 may overlap the plurality of light transmission patterns 115 formed in a concentric circle shape. Through this, the light irradiator 125 may irradiate the light L toward the plurality of light transmission patterns 115.

In some exemplary embodiments, as illustrated in FIG. 5A, a width W2 of the light transmission pattern 115 may be the same as a width W1 of the groove 110G. In the present specification, the term “same” refers to the meaning including not only the completely same, but also a fine difference that may occur due to a margin in a process or the like. In this case, the lower surface of the groove 110G may be defined only by the upper surface of the light transmission pattern 115.

In some exemplary embodiments, the above-described polishing pad 110 may be provided by a 3D printing method. The 3D printing method refers to a technology of three-dimensionalizing electronic information (e.g., a three-dimensional drawing) for implementing a three-dimensional object through an automated output device. Since the 3D printing method may form the required three-dimensional object using an additive fabricating method, it is possible to easily provide the polishing pad 110 including the light transmission pattern 115 described above.

In a chemical mechanical polishing process, a technology of controlling temperature (hereinafter, a polishing temperature) at which a polishing process is performed is emerging as an increasingly important technology to improve polishing efficiency related to productivity (e.g., polishing speed) and defects (e.g., dishing). On the other hand, the polishing temperature control technology on an upper side of the polishing pad 110 where the polishing surface 110S is exposed is relatively easy, while the polishing temperature control technology on a lower side of the polishing pad 110 is difficult as the polishing pad 110 itself acts as a heat insulating material.

However, as the chemical mechanical polishing apparatus according to some exemplary embodiments includes the light irradiator 125 disposed in the platen 120 and the polishing pad 110 including the light transmission pattern 115 on the platen 120, it is possible to efficiently control the polishing temperature even on the lower side of the polishing pad 110. Specifically, as described above, the light L irradiated from the light irradiator 125 may transmit through the light transmission pattern 115 to heat the polishing slurry S. In particular, since the light transmission pattern 115 may be formed to correspond to at least some of the grooves 110G formed in the polishing surface 110S, the light L transmitted through the light transmission pattern 115 may efficiently heat the polishing slurry S flowing through the grooves 110G. Through this, a chemical mechanical polishing apparatus with improved polishing efficiency may be provided by improving polishing temperature control efficiency.

FIGS. 5B to 5F are other various enlarged views illustrating the R region of FIG. 4. For convenience of explanation, portions overlapping those described above with reference to FIGS. 1 to 5A will be briefly described or omitted.

Referring to FIGS. 4 and 5B, in the chemical mechanical polishing apparatus according to some exemplary embodiments, the width W2 of the light transmission pattern 115 may be greater than the width W1 of the groove 110G.

For example, a portion of the base pattern 112 may cover a portion of the upper surface of the light transmission pattern 115. Another portion of the upper surface of the light transmission pattern 115 exposed from the base pattern 112 may define the lower surface of the groove 110G.

Referring to FIGS. 4 and 5C, in the chemical mechanical polishing apparatus according to some exemplary embodiments, the width W2 of the light transmission pattern 115 may be smaller than the width W1 of the groove 110G.

For example, the upper surface of the light transmission pattern 115 may define a portion of the lower surface of the groove 110G, and a portion of the base pattern 112 may define another portion of the lower surface of the groove 110G.

Referring to FIGS. 4 and 5D, in the chemical mechanical polishing apparatus according to some exemplary embodiments, the upper surface of the base pattern 112 may have various heights.

For example, the base pattern 112 may include a first sub-base pattern 112a and a second sub-base pattern 112b having different heights. As an example, based on the upper surface of the light transmission pattern 115, a height H21 at which the first sub-base pattern 112a protrudes may be greater than a height H22 at which the second sub-base pattern 112b protrudes. Through this, the grooves 110G having various depths may be formed as needed.

Referring to FIGS. 4 and 5E, in the chemical mechanical polishing apparatus according to some exemplary embodiments, the upper surface of the light transmission pattern 115 may have various heights.

For example, the light transmission pattern 115 may include a first sub-transmission pattern 115a and a second sub-transmission pattern 115b having different heights. As an example, based on the upper surface of the base pattern 112, a height H31 up to the first sub-transmission pattern 115a may be smaller than a height H32 up to the second sub-transmission pattern 115b. Through this, the grooves 110G having various depths may be formed as needed.

Referring to FIGS. 4 and 5F, in the chemical mechanical polishing apparatus according to some exemplary embodiments, the base pattern 112 may include a lower pattern 112L and an upper pattern 112U.

The lower pattern 112L and the upper pattern 112U may be sequentially stacked on the platen 120 and/or the light irradiator 125. The lower pattern 112L may be disposed on the side surface of the light transmission pattern 115, and the upper pattern 112U may be disposed on an upper surface of the lower pattern 112L.

The lower pattern 112L and the upper pattern 112U may have different physical properties. In some exemplary embodiments, the lower pattern 112L may be softer than the upper pattern 112U. As an example, the lower pattern 112L may include a material having resilience against a force that pressurizes the wafer W to be polished. Through this, the lower pattern 112L may support the upper pattern 112U with a uniform elastic force with respect to the wafer W during the polishing process. In some other exemplary embodiments, the lower pattern 112L may be more rigid than the upper pattern 112U.

Although it is illustrated that a boundary between the lower pattern 112L and the upper pattern 112U exists, this is only an example. As another example, the boundary between the lower pattern 112L and the upper pattern 112U may not exist or may be unclear.

In addition, although it is illustrated that the boundary between the lower pattern 112L and the upper pattern 112U is coplanar with the upper surface of the light transmission pattern 115, this is only an example. As another example, the boundary between the lower pattern 112L and the upper pattern 112U may also be higher than the upper surface of the light transmission pattern 115 or lower than the upper surface of the light transmission pattern 115.

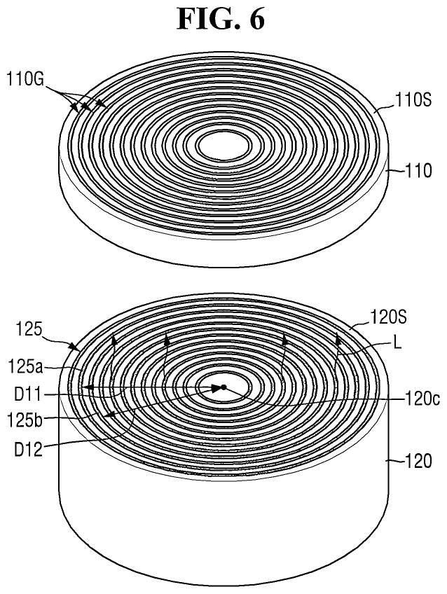

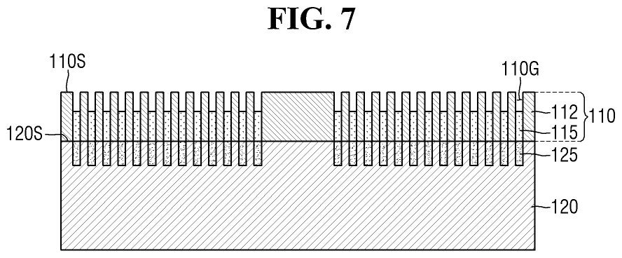

FIG. 6 is a schematic perspective view illustrating the polishing pad, the platen, and the light irradiator of the chemical mechanical polishing apparatus according to some exemplary embodiments. FIG. 7 is a schematic cross-sectional view illustrating the polishing pad, the platen, and the light irradiator of FIG. 6. For convenience of explanation, portions overlapping those described above with reference to FIGS. 1 to 5F will be briefly described or omitted.

Referring to FIGS. 6 and 7, in the chemical mechanical polishing apparatus according to some exemplary embodiments, the light irradiator 125 may be disposed to correspond to the light transmission pattern 115, as illustrated.

For example, when the light transmission pattern 115 is formed in a concentric circle shape, the light irradiator 125 may also be provided in a corresponding concentric circle shape. As an example, the light irradiator 125 may include a first light source portion 125a and a second light source portion 125b each having a ring shape and having different radii. Based on a center 120c of the upper surface 120S of the platen 120, the first light source portion 125a may have a first radius D11, and the second light source portion 125b may have a second radius D12 smaller than the first radius D11.

In some exemplary embodiments, the light irradiator 125 may be provided to correspond to an entire area of the light transmission pattern 115.

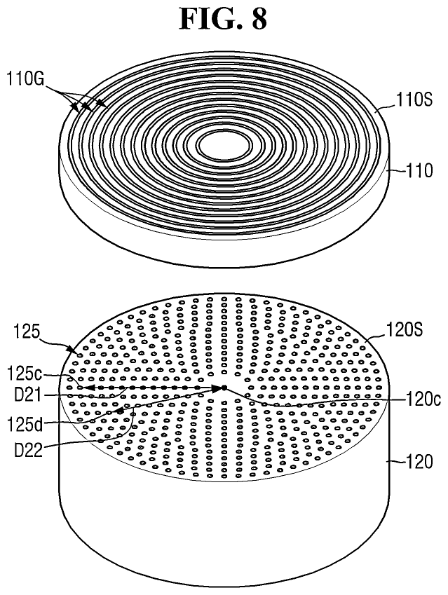

FIG. 8 is a schematic perspective view illustrating the polishing pad, the platen, and the light irradiator of the chemical mechanical polishing apparatus according to some exemplary embodiments. For convenience of explanation, portions overlapping those described above with reference to FIGS. 1 to 5F will be briefly described or omitted.

Referring to FIG. 8, in the chemical mechanical polishing apparatus according to some exemplary embodiments, the light irradiator 125 may include a plurality of light source portions that are spaced apart from each other and each form an isolated area.

As an example, the light irradiator 125 may include a third light source portion 125c and a fourth light source portion 125d each having an island shape (i.e., the light source portions 125c, 125d are isolated/discontinuous and do not extend around the platen 120 as the light source portions 125a, 125b do in FIG. 6). The third light source portion 125c and the fourth light source portion 125d may be spaced apart from each other at different distances based on the center 120c of the upper surface 120S of the platen 120. For example, the third light source portion 125c may be spaced apart from the center 120c of the upper surface 120S of the platen 120 by a first distance D21, and the fourth light source portion 125d may be spaced apart from the center 120c of the upper surface 120S of the platen 120 by a second distance D22 smaller than the first distance D21.

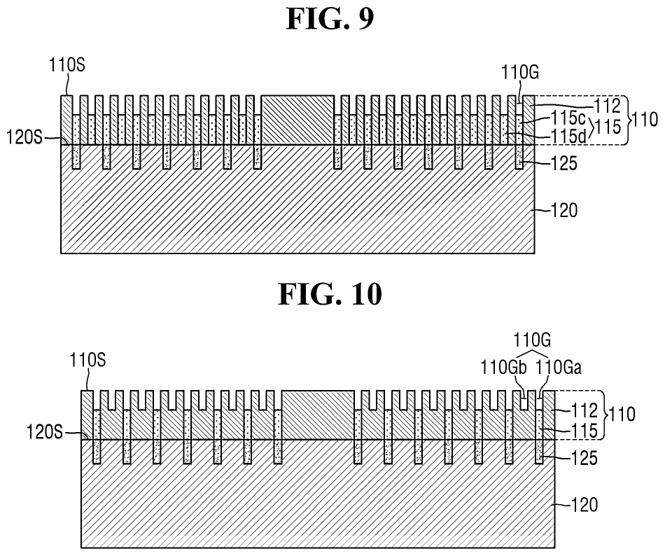

FIGS. 9 and 10 are various schematic cross-sectional views illustrating the polishing pad, the platen, and the light irradiator of the chemical mechanical polishing apparatus according to some exemplary embodiments. For convenience of explanation, portions overlapping those described above with reference to FIGS. 1 to 5F will be briefly described or omitted.

Referring to FIG. 9, in the chemical mechanical polishing apparatus according to some exemplary embodiments, the light irradiator 125 may be provided to correspond to a partial area of the light transmission pattern 115.

For example, the light transmission pattern 115 may include a third sub-transmission pattern 115c and a fourth sub-transmission pattern 115d. The third sub-transmission pattern 115c may overlap the light irradiator 125 in the vertical direction, and the fourth sub-transmission pattern 115d may not overlap the light irradiator 125 in the vertical direction (i.e., the third sub-transmission pattern 115c is in direct optical communication with the light irradiator 125, and the fourth sub-transmission pattern 115d is not in direct optical communication with the light irradiator 125).

Referring to FIG. 10, in the chemical mechanical polishing apparatus according to some exemplary embodiments, the light transmission pattern 115 may be provided to correspond to some areas of grooves 110G.

For example, the grooves 110G may include a first groove 110Ga and a second groove 110Gb. The first groove 110Ga may overlap the light transmission pattern 115 in the vertical direction, and the second groove 110Gb may not overlap the light transmission pattern 115 in the vertical direction. In some exemplary embodiments, a lower surface of the first groove 110Ga may be defined by the light transmission pattern 115 and a lower surface of the second groove 110Gb may be defined by the base pattern 112.

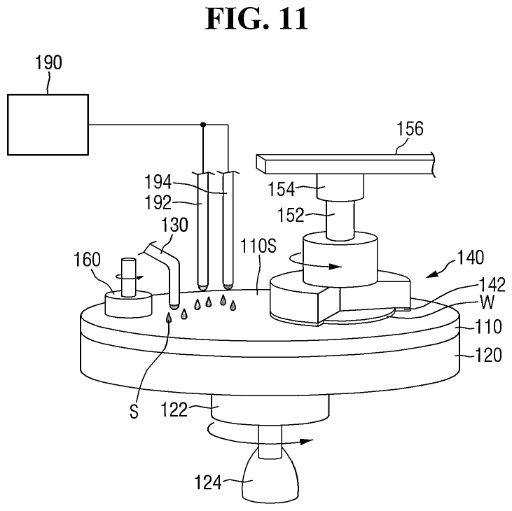

FIG. 11 is a schematic perspective view illustrating the chemical mechanical polishing apparatus according to some exemplary embodiments. For convenience of explanation, portions overlapping those described above with reference to FIGS. 1 to 10 will be briefly described or omitted.

Referring to FIG. 11, the chemical mechanical polishing apparatus according to some exemplary embodiments further includes an upper temperature control unit 190.

The upper temperature control unit 190 may control the polishing temperature on the upper side of the polishing pad 110. As an example, the upper temperature control unit 190 may be connected to process solution suppliers 192 and 194. The process solution suppliers 192 and 194 may supply a process solution to the upper surface (i.e., the polishing surface 110S) of the polishing pad 110 to heat or cool a temperature of the polishing pad 110 on the upper side of the polishing pad 110. The process solution may include, for example, water, but is not limited thereto.

In some exemplary embodiments, the process solution suppliers 192 and 194 may include a first supplier 192 and a second supplier 194. The first supplier 192 and the second supplier 194 may supply process solutions having different temperatures. For example, the first supplier 192 may supply a high-temperature first process solution to the upper surface (i.e., the polishing surface 110S) of the polishing pad 110, and the second supplier 194 may supply a low-temperature second process solution to the upper surface (i.e., the polishing surface 110S) of the polishing pad 110.

Through this, by simultaneously controlling the polishing temperature on both sides (i.e., the lower and upper sides) of the polishing pad 110, the chemical mechanical polishing apparatus with further improved polishing temperature control efficiency may be provided.

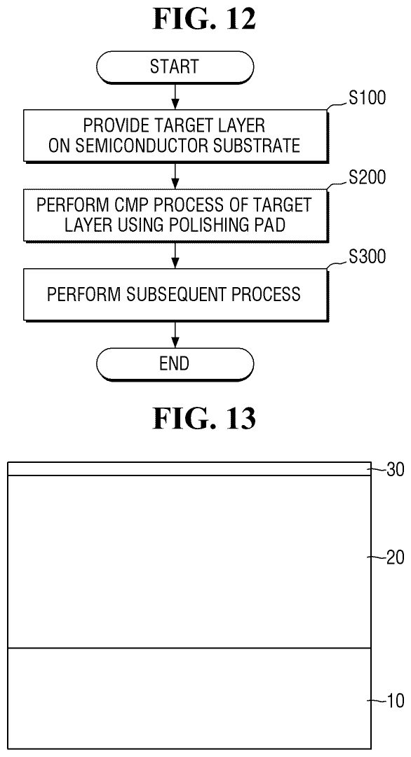

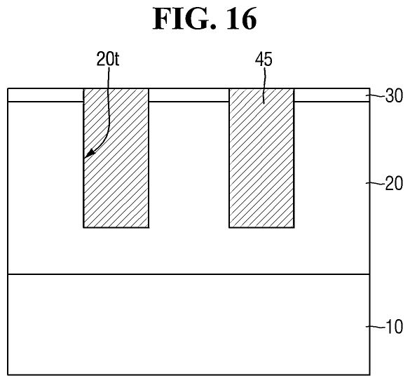

Hereinafter, a method of fabricating a semiconductor device according to exemplary embodiments will be described with reference to FIGS. 12 to 16. However, the following exemplary embodiments are merely illustrative, and the present disclosure is not limited to the exemplary embodiments. For convenience of explanation, portions overlapping those described above with reference to FIGS. 1 to 11 will be briefly described or omitted.

FIG. 12 is an exemplary flowchart illustrating a method of fabricating a semiconductor device according to some exemplary embodiments. FIGS. 13 to 16 are intermediate step drawings illustrating the method of fabricating the semiconductor device according to some exemplary embodiments.

Referring to FIGS. 12 to 15, a target layer 40 is provided on a semiconductor substrate 10 (S100).

For example, as illustrated in FIG. 13, an interlayer insulating layer 20 and an insertion layer 30 may be sequentially formed on the semiconductor substrate 10.

The semiconductor substrate 10 may be bulk silicon or silicon-on-insulator (SOI). Unlike this, the semiconductor substrate 10 may be a silicon substrate, or may include another material, for example, silicon germanium, silicon germanium on insulator (SGOI), indium antimonide, lead tellurium compound, indium arsenide, indium phosphide, gallium arsenide, or gallium antimonide, but is not limited thereto. For convenience of explanation, the semiconductor substrate 10 will be described below as being a silicon substrate.

The interlayer insulating layer 20 may be stacked on the semiconductor substrate 10. The interlayer insulating layer 20 may include, for example, at least one of silicon oxide, silicon nitride, silicon oxynitride, and combinations thereof, but is not limited thereto.

The insertion layer 30 may be stacked on the interlayer insulating layer 20. The insertion layer 30 may function as an etch stop layer in a chemical mechanical polishing process described later.

Subsequently, as illustrated in FIG. 14, a trench 20t may be formed in the interlayer insulating layer 20 and the insertion layer 30. The trench 20t may be formed by etching a portion of the interlayer insulating layer 20 and a portion of the insertion layer 30. In some exemplary embodiments, the trench 20t may have a width of about 10 nm or less.

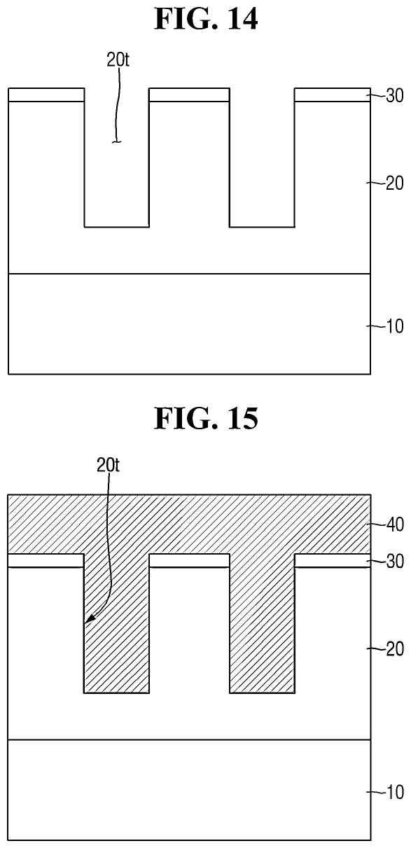

Subsequently, as illustrated in FIG. 15, a target layer 40 may be formed on the interlayer insulating layer 20 and the insertion layer 30. The target layer 40 may be formed to fill the trench 20t.

The target layer 40 may include at least one of a semiconductor material, a conductive material, an insulating material, and a combination thereof. As an example, the target layer 40 may include a semiconductor material such as polysilicon and/or an epitaxial layer. As another example, the target layer 40 may include a conductive material such as doped polysilicon, metal, metal silicide, and/or metal nitride. As still another example, the target layer 40 may include an insulating material such as silicon oxide, silicon nitride, silicon oxynitride, a low-k material having a lower dielectric constant than silicon oxide, and/or a high-k material having a higher dielectric constant than silicon oxide.

Although it is only illustrated that the target layer is formed as a single layer, this is merely an example, and the target layer 40 may also be formed as multiple layers in which a plurality of layers is stacked. As an example, the target layer 40 may include a plurality of stacked insulating layers, and may also include a conductive layer or a semiconductor layer interposed between the stacked insulating layers.

Referring to FIGS. 12, 15, and 16, a chemical mechanical polishing process is performed on the target layer 40 (S200).

The chemical mechanical polishing process on the target layer 40 may be performed using the chemical mechanical polishing apparatus described above with reference to FIGS. 1 to 11. For example, the polishing pad 110, the platen 120, and the light irradiator 125 described above with reference to FIGS. 1 to 11 may be provided. In addition, the polishing slurry S may be provided between the semiconductor substrate 10 on which the target layer 40 is formed and the polishing pad 110 through the slurry supplier 130. The target layer 40 may rotate while being in contact with the polishing pad 110 through the carrier head assembly 140. While the polishing process is performed, the light L irradiated from the light irradiator 125 may transmit through the light transmission pattern 115 of the polishing pad 110 to heat the polishing slurry S. Through this, the chemical mechanical polishing process may provide improved polishing efficiency.

The chemical mechanical polishing process may be performed until the insertion layer 30 is exposed, for example. Through this, a target pattern 45 filling the trench 20t may be formed.

Subsequently, referring to FIG. 12, a subsequent process is performed (S300).

The subsequent process may include various semiconductor processes for the semiconductor substrate 10 and/or the target pattern 45. For example, the semiconductor processes may include, but are not limited to, a deposition process, an etching process, an ion process, and a cleaning process. The semiconductor processes may also include a test process for semiconductor devices at a wafer level. As the subsequent process is performed, various integrated circuits and wirings required for the semiconductor device may be formed.

When semiconductor chips are formed on the semiconductor substrate 10 through the semiconductor processes, the respective semiconductor chips may be individualized. The individualization of the respective semiconductor chips may be performed through a sawing process using a blade or a laser, for example. Subsequently, a packaging process may be performed on each of the semiconductor chips. The packaging process may refer to a process of mounting each of the semiconductor chips on a circuit board (e.g., a printed circuit board (PCB)) and sealing each of the semiconductor chips with a sealing material. In addition, the packaging process may include forming a stack package by stacking a plurality of semiconductor chips in multiple layers on the circuit board, or forming a package on package (POP) structure by stacking a stack package on a stack package. A semiconductor package may be formed through the packaging process on the respective semiconductor chips. The semiconductor processes may also include a test process for semiconductor devices at a package level.

While the present inventive concept has been particularly shown and described with reference to exemplary embodiments thereof, it will be understood by those of ordinary skill in the art that various changes in form and details may be made therein without departing from the scope of the present inventive concept as defined by the following claims. It is therefore desired that the present embodiments be considered in all respects as illustrative and not restrictive, reference being made to the appended claims rather than the foregoing description to indicate the scope of the invention.

What is claimed is:

1. A method of fabricating a semiconductor device, the method comprising:
providing a target layer on a semiconductor substrate; and
performing a polishing process on the target layer using a chemical mechanical polishing apparatus,
wherein the chemical mechanical polishing apparatus comprises:
a platen;
a polishing pad on the platen, the polishing pad comprising a plurality of grooves; and
a light irradiator in the platen, the light irradiator configured to irradiate light toward the polishing pad, and
wherein the polishing pad comprises a light transmission pattern within at least some of the plurality of grooves and through which the light is transmitted from the light irradiator.

2. The method of claim 1, wherein the performing the polishing process comprises:
providing the target layer on the polishing pad; and
providing a polishing slurry between the polishing pad and the target layer.

3. The method of claim 2, wherein the light transmitted through the light transmission pattern heats the polishing slurry.

4. The method of claim 1, wherein the light includes infrared light.

5. The method of claim 1, wherein the polishing pad comprises at least one of polyurethane, polyester, polyether, felt, epoxy, polyimide, polycarbonate, polyethylene, polypropylene, latex, nitrile-butadiene rubber (NBR), and isoprene rubber, and wherein the light transmission pattern comprises at least one of polyethylene and polyethylene terephthalate.

6. A chemical mechanical polishing apparatus, comprising:
a platen;
a polishing pad on the platen, the polishing pad comprising a plurality of grooves; and
a light irradiator in the platen, the light irradiator configured to irradiate light toward the polishing pad,
wherein the polishing pad comprises a light transmission pattern within at least some of the plurality of grooves and through which the light is transmitted from the light irradiator.

7. The chemical mechanical polishing apparatus of claim 6, wherein the light includes infrared light.

8. The chemical mechanical polishing apparatus of claim 6, wherein the polishing pad further comprises a base pattern, and wherein the light transmission pattern is retained within the base pattern,
wherein the base pattern defines a side surface of each of the grooves, and
wherein the light transmission pattern defines a lower surface of each of the grooves.

9. The chemical mechanical polishing apparatus of claim 8, wherein the base pattern comprises a lower pattern and an upper pattern on an upper surface of the lower pattern, and
wherein the lower pattern and the upper pattern have different physical properties from each other.

10. The chemical mechanical polishing apparatus of claim 8, wherein the base pattern comprises a polymer.

11. The chemical mechanical polishing apparatus of claim 6, wherein the light transmission pattern comprises at least one of polyethylene and polyethylene terephthalate.

12. The chemical mechanical polishing apparatus of claim 6, wherein an upper surface of the platen comprises at least one opening through which light from the light irradiator can be transmitted to the polishing pad.

13. The chemical mechanical polishing apparatus of claim 6, wherein the light irradiator comprises a plurality of light source portions radially spaced outward from a center of an upper surface of the platen by respective different distances.

14. The chemical mechanical polishing apparatus of claim 13, wherein the plurality of light source portions are concentric.

15. The chemical mechanical polishing apparatus of claim 6, wherein the light transmission pattern comprises a first sub-transmission pattern that is in direct optical communication with the light irradiator and a second sub-transmission pattern that is not in direct optical communication with the light irradiator.

16. The chemical mechanical polishing apparatus of claim 6, wherein the plurality of grooves comprise a first groove in direct optical communication with the light transmission pattern, and a second groove not in direct optical communication with the light transmission pattern.

17. A chemical mechanical polishing apparatus, comprising:
a rotatable platen;
a polishing pad on the platen, the polishing pad comprising a polishing surface, a plurality of grooves formed in the polishing surface, and a light transmission pattern within at least some of the plurality of grooves;
a carrier head assembly above the polishing pad and configured to support a wafer facing the polishing surface;
a slurry supplier configured to supply a polishing slurry between the wafer and the polishing pad; and
a light irradiator in the platen, the light irradiator configured to irradiate light toward the light transmission pattern.

18. The chemical mechanical polishing apparatus of claim 17, wherein the light includes infrared light.

19. The chemical mechanical polishing apparatus of claim 17, wherein the light is transmitted through the light transmission pattern to heat the polishing slurry.

20. The chemical mechanical polishing apparatus of claim 17, wherein the polishing pad comprises at least one of polyurethane, polyester, polyether, felt, epoxy, polyimide, polycarbonate, polyethylene, polypropylene, latex, nitrile-butadiene rubber (NBR), and isoprene rubber, and wherein the light transmission pattern comprises at least one of polyethylene and polyethylene terephthalate.
